(19) United States
(12) Patent Application Publication
(10) Pub. No.: US 2013/0203237 A1
(43) Pub. Date: Aug. 8, 2013

(54) CUTTING METHOD FOR DEVICE WAFER

(71) Applicant: Disco Corporation, Tokyo (JP)

(72) Inventors: Akira YAMAGUCHI, Tokyo (JP); Toshiharu DAII, Tokyo (JP); Shigeyuki IKEDA, Saitama-city (JP)

(73) Assignee: DISCO CORPORATION, Tokyo (JP)

(21) Appl. No.: 13/754,386

(22) Filed: Jan. 30, 2013

(30) Foreign Application Priority Data
Feb. 7, 2012 (JP) 2012-023756

(51) Int. Cl. H01L 21/78

(52) U.S. Cl. CPC H01L 21/78
USPC 438/460

(57) ABSTRACT

A cutting method for cutting a device wafer along a plurality of crossing division lines by using a cutting blade, the division lines being formed on the front side of the device wafer to partition a plurality of regions where a plurality of devices are respectively formed. The cutting method includes a hydrophilic property providing step of applying a plasma to the front side of the device wafer to thereby make hydrophilic the front side of the device wafer, and a cutting step of cutting the device wafer along the division lines by using the cutting blade as supplying a cutting fluid to the device wafer after performing the hydrophilic property providing step.

### BACKGROUND OF THE INVENTION

1. Field of the Invention

The present invention relates to a cutting method for cutting a device wafer having a plurality of devices on the front side thereof by using a cutting blade.

2. Description of the Related Art

In a semiconductor device fabrication process, a plurality of crossing division lines are formed on the front side of a semiconductor wafer to thereby partition a plurality of regions where a plurality of semiconductor devices are respectively formed. The back side of the semiconductor wafer is ground by a grinding apparatus to reduce the thickness of the wafer to a predetermined thickness. Thereafter, the semiconductor wafer is cut along the division lines by using a cutting apparatus to thereby obtain the individual semiconductor devices as semiconductor chips divided from each other.

Widely used as the cutting apparatus is a dicing apparatus called a dicing saw having a cutting unit including a cutting blade. The cutting blade is obtained by binding super abrasive grains such as diamond and CBN (Cubic Boron Nitride) with metal or resin. In the cutting apparatus, the cutting blade is rotated at a high speed, e.g., at 30000 rpm and is fed along the division lines on the workpiece to thereby cut the workpiece.

If impurities stick to a device wafer such as a semiconductor wafer, they have a serious effect on the quality of each device. Therefore, in cutting and grinding the device wafer, pure water or ultrapure water having a resistivity of about 1 to 10 MΩ·cm or more is used as a processing water. However, since the pure water has a high resistivity and its insulating property is very high, static electricity is generated by the friction due to the flow of the pure water, causing electrostatic discharge damage to the devices or adhesion of cut dust to the workpiece. To cope with this problem, carbon dioxide is mixed with the pure water to obtain a mixed fluid, which is used as a cutting fluid. This method is widely adopted (see Japanese Patent Laid-open No. 2003-291065, for example).

### SUMMARY OF THE INVENTION

Cutting of a usual device wafer such as a semiconductor wafer is performed as supplying a cutting fluid to the wafer, thereby suppressing heating of the cutting blade. Further, cut dust can be removed from the device wafer by the cutting fluid. However, in a device wafer having a plurality of optical devices including an imaging device such as CCD and CMOS, an ink jet head, a filter, and an optical pickup device, there is an optical device wafer having high water repellency such that the contact angle to pure water is 60° or more.

In the case that cutting of such an optical device wafer having high water repellency is performed as supplying a cutting fluid to the wafer, the cutting fluid is repelled by the front side of the wafer, so that it is difficult to remove the cut dust from the front side of the wafer by using the cutting fluid. When the device wafer is dried in the condition where the cut dust sticks to the front side of the wafer, there arises a problem such that the cut dust may be fixed to the front side of the wafer and it cannot be removed even by cleaning with pure water in a subsequent step.

It is therefore an object of the present invention to provide a cutting method for a device wafer which can reduce unwanted matter sticking to the surface of each device.

In accordance with an aspect of the present invention, there is provided a cutting method for cutting a device wafer along a plurality of crossing division lines by using a cutting blade, the division lines being formed on the front side of the device wafer to partition a plurality of regions where a plurality of devices are respectively formed, the cutting method including a hydrophilic property providing step of applying a plasma to the front side of the device wafer to thereby make hydrophilic the front side of the device wafer; and a cutting step of cutting the device wafer along the division lines by using the cutting blade as supplying a cutting fluid to the device wafer after performing the hydrophilic property providing step.

According to the cutting method of the present invention, the front side of the device wafer is processed to have a hydrophilic property by applying the plasma prior to performing the cutting step. Accordingly, the cut dust generated during cutting can be removed by the cutting fluid from the front side of the device wafer, so that unwanted matter sticking to the surface of each device can be reduced.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a device wafer;

FIG. 2 is a schematic elevational view of a plasma cleaning apparatus;

FIG. 3 is a perspective view of the device wafer in the condition where it is supported through a dicing tape to an annular frame; and

FIG. 4 is a perspective view showing a cutting step.

### DETAILED DESCRIPTION OF THE PREFERRED EMBODIMENT

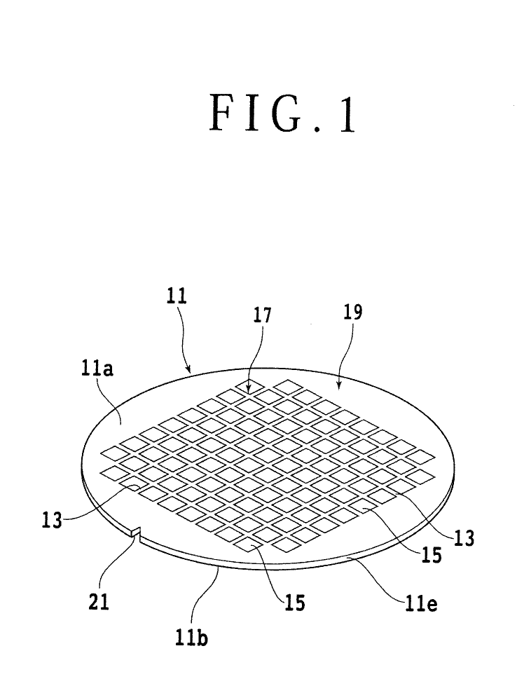

A preferred embodiment of the present invention will now be described in detail with reference to the drawings. Referring to FIG. 1, there is shown a perspective view of a device wafer 11 as a workpiece to be cut by the cutting method of the present invention. The device wafer 11 is formed from a silicon wafer having a thickness of 700 μm, for example. A plurality of crossing division lines (streets) 13 are formed on the front side 11a of the device wafer 11, thereby partitioning a plurality of rectangular regions where a plurality of imaging devices 15 such as CCDs and CMOSs are respectively formed. The front side 11a of the device wafer 11 is a flat portion and includes a device area 17 where the imaging devices 15 are formed and a peripheral marginal area 19 surrounding the device area 17. The outer circumference of the device wafer 11 is formed as an arcuate chamfered portion 11e ranging from the front side 11a to the back side 11b of the device wafer 11. The outer circumference of the device wafer 11 is formed with a notch 21 as a mark for indicating the crystal orientation of the silicon wafer.

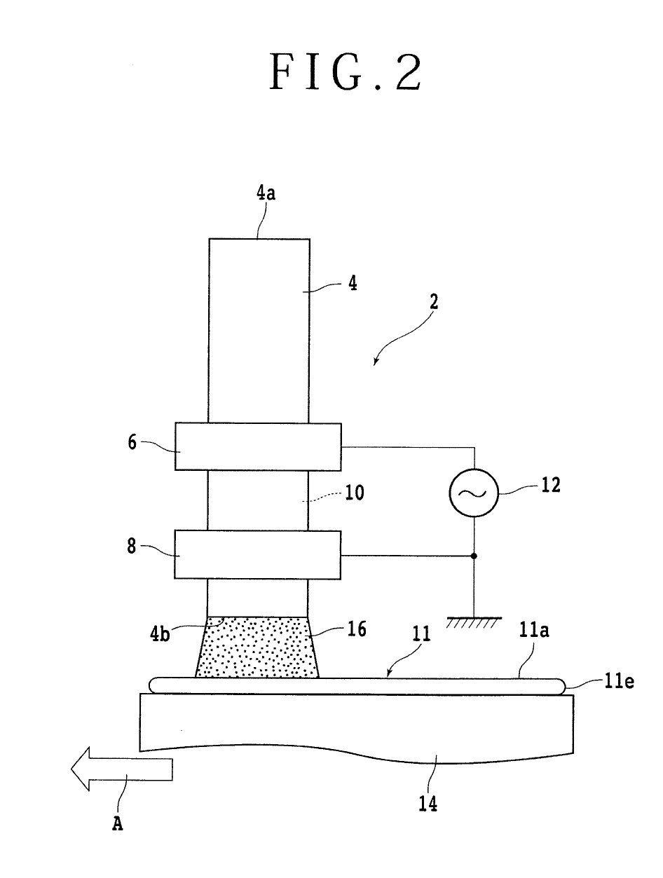

According to the cutting method of the present invention, a hydrophilic property providing step is performed as a first step in such a manner that a plasma is applied to the front side 11a of the device wafer 11 to thereby make hydrophilic the front side 11a of he device wafer 11. For example, this hydrophilic priperty providing step is performed by using a plasma cleaning apparatus 2 shown in FIG. 2. Reference numeral 4 denotes a reactor of the plasma cleaning apparatus 2. A pair of electrodes 6 and 8 are provided around the outer circumference of the reactor 4 in full contact therewith. A discharge space 10 is formed in the reactor 4 at a position corresponding to the space between the electrodes 6 and 8. The electrodes 6 and 8 are connected through an impedance matching circuit (not shown) to an AC power supply 12 for generating a high alternating voltage in the discharge space 10. The electrode 8 is grounded.

The reactor 4 is formed of an insulating material having a high melting point, and it has a substantially cylindrical shape. The permittivity of the insulating material forming the reactor 4 is an important factor in lowering the temperature of the plasma in the discharge space 10, and preferable examples of this insulating material include glass materials and ceramic materials such as quartz, alumina, and yttria partially stabilized zirconium. The upper end of the reactor 4 is open as a gas inlet 4a, and the lower end of the reactor 4 is also open as a plasma outlet 4b. The plasma outlet 4b is communicated with the discharge space 10 in the reactor 4.

The electrodes 6 and 8 are formed of a metal material such as copper, aluminum, brass, and stainless steel having high corrosion resistance. The space between the electrodes 6 and 8 is preferably set to about 3 to 20 mm in order to stably generate the plasma. The AC power supply 12 is capable of generating a voltage (e.g., 0.5 to 5 kV) required to continuously generate the plasma in the discharge space 10 and applying this voltage through the electrodes 6 and 8 to the discharge space 10. The frequency of the AC electric field to be applied to the discharge space 10 is preferably set to 1 kHz to 200 MHz. In the hydrophilic property providing step using the plasma cleaning apparatus 2, a mixed gas composed of argon (Ar) and hydrogen gas (H₂) is preferably used as a plasma generating gas. The plasma generating gas may contain helium (He).

There will now be described the hydrophilic property providing step of cleaning the front side 11a of the device wafer 11 by using the plasma cleaning apparatus 2 to thereby make hydrophilic the front side 11a of the device wafer 11. The device wafer 11 is held under suction on a holding table 14 included in the plasma cleaning apparatus 2 in the condition where the front side 11a of the device wafer 11 is oriented upward. The plasma generating gas is next introduced from the gas inlet 4a into the reactor 4. The plasma generating gas is allowed to flow downward and supplied to the discharge space 10.

A high alternating voltage is next applied from the AC power supply 12 through the impedance matching circuit to the electrodes 6 and 8, thereby applying a high alternating voltage to the discharge space 10 in the reactor 4. As a result, a glow discharge is generated in the discharge space 10 under a pressure near the atmospheric pressure by the high alternating voltage applied to the discharge space 10, so that the plasma generating gas is continuously converted into a plasma 16 containing plasma active species by this glow discharge. The plasma 16 thus generated is allowed to continuously flow downward from the plasma outlet 4b in the form of a jet and sprayed onto the front side 11a of the device wafer 11 held on the holding table 14.

The plasma 16 is applied to the front side 11a of the device wafer 11 as moving the holding table 14 in the direction shown by an arrow A in FIG. 2. Thereafter, the holding table 14 is moved in the direction perpendicular to the direction of the arrow A (i.e., in the direction perpendicular to the sheet plane of FIG. 2) by a distance substantially equal to the width of the jet of the plasma 16 sprayed from the plasma outlet 4b. Thereafter, the plasma 16 is applied again to the front side 11a of the device wafer 11 as moving the holding table 14 in the direction of the arrow A. In this manner, the plasma 16 is finally applied to the whole surface of the front side 11a of the device wafer 11 to thereby make hydrophilic the front side 11a of the device wafer 11. Accordingly, the water repellency of the front side 11a of the device wafer 11 is reduced by the hydrophilic property providing step using the application of the plasma 16. In addition, organic matter on the device wafer 11 can also be removed by the application of the plasma 16.

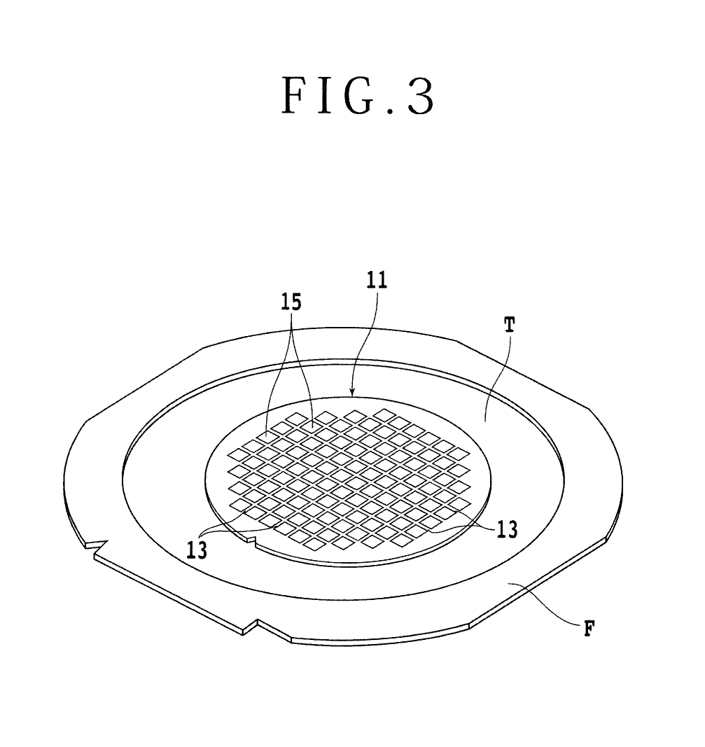

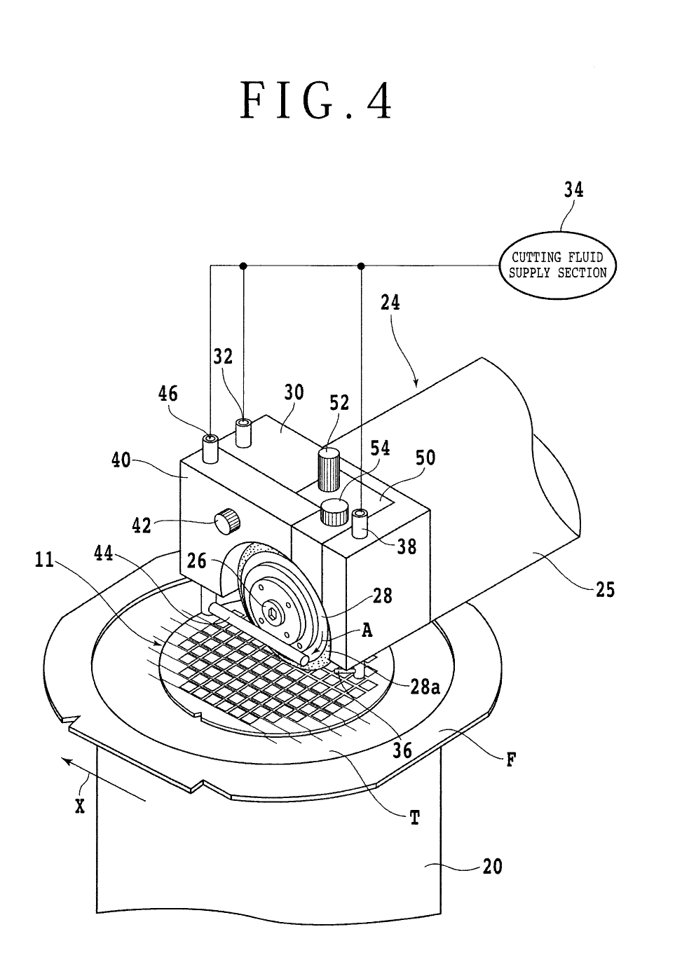

After performing the hydrophilic property providing step, the device wafer 11 is attached to a dicing tape T as an adhesive tape supported at its outer circumferential portion to an annular frame F as shown in FIG. 3. Accordingly, the device wafer 11 is supported through the dicing tape T to the annular frame F. Thereafter, a cutting step is performed in such a manner that the device wafer 11 is cut along the division lines 13 by a cutting blade as supplying a cutting fluid to the device wafer 11. This cutting step will now be described with reference to FIG. 4.

Reference numeral 24 denotes a cutting unit in a cutting apparatus. The cutting unit 24 includes a spindle housing 25, a spindle 26 accommodated in the spindle housing 25 so as to be rotationally driven by a servo motor (not shown), and a cutting blade 28 mounted on an end portion of the spindle 26. The cutting blade 28 is formed by electroforming and has a cutting edge 28a around the outer circumference thereof. The cutting edge 28a is composed of a nickel base and diamond abrasive grains dispersed in the nickel base. Reference numeral 30 denotes a blade cover for covering the cutting blade 28. A cooling fluid nozzle (not shown) extending along one side surface of the cutting blade 28 is mounted on the blade cover 30. Further, a cutting fluid nozzle 36 for supplying a cutting fluid to a cutting area between the cutting edge 28a of the cutting blade 28 and the device wafer 11 is also mounted on the blade cover 30.

The cutting fluid is a mixed fluid composed of pure water and carbon dioxide gas, and it is supplied from a cutting fluid supply section 34 through a pipe 32 to the cooling fluid nozzle (not shown) mounted on the blade cover 30. The cutting fluid from the cutting fluid supply section 34 is also supplied through a pipe 38 to the cutting fluid nozzle 36. The cutting fluid is pressurized at about 0.3 MPa in the cutting fluid supply section 34 and directed at a flow rate of 1.6 to 2.0 liters/min from the cutting fluid nozzle 36.

Reference numeral 40 denotes a detachable cover, which is detachably mounted on the blade cover 30 by means of a screw 42. The detachable cover 40 has a cooling fluid nozzle 44 extending along the other side surface of the cutting blade 28. The cutting fluid from the cutting fluid supply section 34 is supplied through a pipe 46 to the cooling fluid nozzle 44. Reference numeral 50 denotes a blade detecting block incorporating a blade sensor for detecting chipping of the cutting edge 28a of the cutting blade 28. The blade detecting block 50 is detachably mounted on the blade cover 30 by means of a screw 52. The blade detecting block 50 has an adjusting screw 54 for adjusting the position of the blade sensor.

In the cutting step, the device wafer 11 whose front side 11a has been processed to have a hydrophilic property is held under suction through the dicing tape T on a chuck table 20 included in the cutting apparatus as shown in FIG. 4. In this condition, the device wafer 11 is cut along the division lines 13 by the cutting blade 28 as supplying the cutting fluid from the cutting fluid nozzle 36, the cooling fluid nozzle 44, and the cooling fluid nozzle (not shown) mounted on the blade cover 30.

In this cutting step, the cutting blade 28 is rotated at a high speed (e.g., 30000 rpm) and is lowered to cut into the device wafer 11 from the front side 11a by a predetermined depth. In this condition, the chuck table 20 is moved in the direction shown by an arrow X in FIG. 4 to thereby cut the device wafer 11 along one of the division lines 13 extending in a first direction. Thereafter, the cutting blade 28 is indexed in the direction shown by an arrow Y perpendicular to the arrow X in FIG. 4 and the device wafer 11 is cut along all of the division lines 13 extending in the first direction. Thereafter, the chuck table 20 is rotated 90° and the device wafer 11 is further cut along all of the division lines 13 extending in a second direction perpendicular to the first direction, thus dividing the device wafer 11 into individual device chips.

According to the cutting method of the present invention, the front side 11a of the device wafer 11 is processed to have a hydrophilic property by applying the plasma prior to performing the cutting step. Accordingly, the cut dust generated during cutting can be removed by the cutting fluid from the front side 11a of the device wafer 11, so that unwanted matter sticking to the surface of each device 15 can be reduced.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting method for cutting a device wafer along a plurality of crossing division lines by using a cutting blade, said division lines being formed on the front side of said device wafer to partition a plurality of regions where a plurality of devices are respectively formed, said cutting method comprising:
a hydrophilic property providing step of applying a plasma to the front side of said device wafer to thereby make hydrophilic the front side of said device wafer; and
a cutting step of cutting said device wafer along said division lines by using said cutting blade as supplying a cutting fluid to said device wafer after performing said hydrophilic property providing step.
